(19) United States
(12) Patent Application Publication
(10) Pub. No.: US 2002/0066535 A1
(43) Pub. Date: Jun. 6, 2002

(54) EXHAUST SYSTEM FOR TREATING PROCESS GAS EFFLUENT

(76) Inventors: WILLIAM BROWN, SAN JOSE, CA (US); HARALD HERCHEN, SAN JOSE, CA (US); MICHAEL D. WELCH, LIVERMORE, CA (US)

Correspondence Address: PATENT COUNSEL, LEGAL AFFAIRS DEPARTMENT, APPLIED MATERIALS INC, P O BOX 450A, SANTA CLARA, CA, 95052

(21) Appl. No.: 09/055,201

(22) Filed: Apr. 3, 1998

Related U.S. Application Data
(63) Continuation-in-part of application No. 08/499,984, filed on Jul. 10, 1995, now abandoned.

(51) Int. Cl. C23F 1/02; C23C 16/00

(52) U.S. Cl. 156/345.29; 118/715; 156/345.24; 118/712

(57) ABSTRACT

The present invention relates to a process chamber 25 for processing a substrate 35 in process gas and reducing emissions of hazardous gas to the environment. The process chamber 25 comprises a support 30 for supporting the substrate 35, and a gas distributor 55 for introducing process gas into the process chamber 25. A gas treatment apparatus 75 is provided to treat and exhaust an effluent from the process chamber 25. The gas treatment apparatus 75 comprises an exhaust system having an exhaust tube 85, and a gas energizer 90 for energizing the effluent in the exhaust tube 85 by microwaves or by RF energy, while a continuous flow of effluent flows through the exhaust tube 85 to reduce the hazardous gas content of the effluent. A computer controller system comprising computer program code operates the process chamber and gas treatment apparatus 75.

### CROSS-REFERENCE

This application is a continuation-in-part of U.S. patent application Ser. No. 08/499,984, entitled “MICROWAVE PLASMA BASED APPLICATOR,” to Harald Herchen and William Brown, filed Jul. 10, 1995, which is incorporated herein by reference.

### BACKGROUND

The present invention relates to a gas treatment apparatus for reducing the hazardous gas content of effluent from a semiconductor process chamber.

Fluorocarbon, chlorofluorocarbons, hydrocarbon, and other fluorine containing gases are widely used in the manufacture of integrated circuits. These gases are chemically toxic to humans and hazardous to the environment because they strongly absorb infrared radiation and have high global warming potentials. Especially notorious are persistent fluorinated compounds (PFCs) which are long-lived, chemically stable compounds, such as CF₄, C₂F₆, SF₆, C₃F₈, and CH₃F, that have lifetimes exceeding thousands of years. For example, CF₄ has a lifetime in the environment of about 50,000 years and can contribute to global warming for up to 6.5 million years. In the U.S. semiconductor industry, annual emissions of PFCs are projected to exceed 2.1 million metric tons by the year 2000. Concern over these increased emissions has led to regulations and agreements by the U.S. Environmental Protection Agency and the semiconductor industry to reduce and eventually eliminate the PFC emissions. Thus it is desirable to have an apparatus or method that can eliminate or reduce the hazardous gas content of effluent from semiconductor process chambers.

One conventional apparatus 10 for reducing the PFC emission of effluent gas, as illustrated in FIG. 1, comprises an abatement chamber 112 between the semiconductor process chamber 14 and a vacuum pump 16, that is used to energize effluent gas by microwave energy and a magnetic field of the proper strength to abate the hazardous gas emissions of the effluent. The microwave field enters the abatement chamber 12 through a window 18 to encounter a magnetic field formed by a permanent magnet 20 on the opposite side of the abatement chamber, such that the direction of propagation of the microwave field is parallel to the magnetic field lines in the center of the abatement chamber. The magnet 20 creates electron cyclotron resonance (ECR) in a plane in the middle of the abatement chamber, which causes the energized effluent gas species to gyrate around the magnetic field lines with a rotational frequency proportional to the strength of the magnetic field. The abatement chamber configuration and associated magnetic field cause the energized effluent gas species to travel through the abatement chamber 12 in the circular pathway, to increase microwave power absorption into the effluent gas by “stirring” the energized effluent gas species in the confined abatement chamber. In addition, the abatement chamber 12 comprises an effluent inlet 22 that is offset from an outlet 24 to force the effluent gas to take a circuitous pathway from the inlet to the outlet to further increase microwave absorption. However, the circuitous pathway of the effluent gas reduces the rate at which the process gas effluent can be removed from the process chamber 14 and treated to remove hazardous gas content. It is desirable to have a gas treatment apparatus having an effluent flow pathway that is not circuitously, directed through offset gas inlets and outlets, and that provides the desired rate of effluent abatement.

Another problem with the conventional abatement chamber 12 is its square shape which includes corners and recesses that result in stagnant regions in which gas phase nucleations produce solid phase byproducts that deposit on the internal surfaces of the abatement chamber 12. The solid phase byproducts can also back diffuse into the process chamber 14 to contaminate the processing environment. It is desirable to have an abatement chamber 12 that eliminates these stagnant regions and reduces the formation or deposition of byproduct deposits in the chamber 12.

Yet another problem occurs because conventional abatement chambers 12 are typically formed of aluminum which rapidly erodes in a plasma of fluorine-containing gases to reduce the chamber's operating life and increase maintenance costs. The material used to fabricate the abatement chamber 12 also limits the power level of the microwave energy coupled to the effluent in the chamber because high power levels form plasmas that erode the abatement chamber. At the lower plasma power levels, either the efficiency in abatement of the hazardous gas content of the effluent in the abatement chamber 12 is reduced, or the rate of flow of effluent through the abatement chamber must be lowered, both of which are undesirable. It is desirable to have a gas abatement apparatus 10 made of an erosion resistant material that allows use of a high power level plasma and the high flow rate of effluent thorough the abatement chamber 12.

Accordingly, there is a need for a gas treatment apparatus and method that can reduce or eliminate the hazardous gas content of effluent from a semiconductor process chamber. It is further desirable to have a gas treatment apparatus having an effluent flow pathway that is non-circuitous and allows the unrestricted flow of the effluent gas through the abatement chamber to reduce the hazardous gas content emissions without forming excessive byproduct deposits or reducing process throughput. There is also need for a gas treatment apparatus that is resistant to erosion by the effluent gas arid allows a higher power level of microwave or RF energy to be coupled to the effluent gas.

### SUMMARY

The present invention relates to a semiconductor process chamber and a gas treatment apparatus for reducing the hazardous gas content of effluent from a semiconductor process chamber. The process chamber comprises a support for holding the substrate in the chamber, a gas distributor for distributing process gas in the process chamber, and a gas treatment apparatus comprising (i) an exhaust tube for exhausting effluent from the process chamber, and (ii) a gas energizer for energizing the effluent flowing through in the exhaust tube. The hazardous gas content of the effluent formed during processing of the substrate is reduced, by flowing a continuous stream of effluent through the exhaust tube and coupling microwaves or RF energy into the effluent in the exhaust tube to reduce the hazardous gas content in the continuous stream of effluent without recirculation the effluent in the exhaust tube.

Preferably, the exhaust tube comprises a cylinder having an internal flow surface that is parallel to the direction of the flow of the effluent through the exhaust tube and is substantially absent projections or recesses that alter the effluent flow path. The exhaust tube also comprises a length that is sufficiently long to reduce the hazardous gas content of a continuous stream of effluent that flows through the exhaust tube without recirculation the effluent in the exhaust tube. Preferably, the length of the exhaust tube is sufficiently long to provide a residence time of effluent in the exhaust tube that is at least about 0.1 seconds.

Preferably, the gas energizer comprises a microwave generator for generating microwaves and a waveguide for coupling microwaves from the microwave generator to the exhaust tube to energize the effluent by microwaves, and the exhaust tube is composed of monocrystalline sapphire that is resistant to erosion in halogen gases and that is transparent to the microwaves. Another version of the gas energizer comprises a plasma generator for coupling RF energy into the exhaust tube to generate a plasma from the effluent, the plasma generator comprising facing electrodes or an inductor coil.

In yet another version, the gas treatment apparatus comprises a gas analyzer for monitoring the hazardous gas content of the effluent in the exhaust tube and provides an output signal in relation to the hazardous gas content of the effluent. A computer controller system comprises a computer readable medium having computer readable program code embodied therein for monitoring the output signal from the gas analyzer. When the hazardous gas content of the effluent exceeds a safety level, the computer controller system performs at least one of the following steps: (i) adjusting the operating power level of the gas energizer to reduce the hazardous gas content in the effluent; (ii) adjusting the process conditions in the process chamber to reduce the hazardous gas content in the effluent; (iii) activating an alarm or metering display; (iv) adding a reagent gas to the effluent gas before or after the effluent gas is energized, to reduce the hazardous gas content in the effluent; or (v) terminating the process being conducted in the process chamber.

In a preferred structure, the computer readable program code on the computer readable medium comprises: (1) gas analyzer program code for receiving the output signals relating to the hazardous gas content of the effluent from the gas analyzer and storing or passing the output signals to other program codes; (2) gas energizer program code for adjusting a power level of the gas energizer in relation to the output signals; (3) reagent gas program code for operating a reagent gas mixer that adds the reagent gas to the effluent in relation to the output signals; and (4) safety operational program code that when the output signal from the gas analyzer indicates that the hazardous gas content of the energized effluent exceeds a safety level, performs at least one of the steps of (i) adjusting process conditions in the process chamber to reduce the hazardous gas emissions, (ii) operating an alarm to indicate a dangerous level of toxic or hazardous gas in the effluent, (iii) providing a metering display that shows in real time the level of emissions of hazardous gas, or (iv) shutting down the process chamber.

### DRAWINGS

These features, aspects, and advantages of the present invention will become better understood with regard to the following description, appended claims, and accompanying drawings which illustrate examples of the invention, where:

FIG. 1 (prior art) is a schematic sectional side view of a conventional abatement chamber for treating effluent from a semiconductor process chamber;

FIG. 2 is a schematic side sectional side view of a semiconductor process chamber comprising a gas treatment apparatus according to the present invention;

FIG. 3a is a schematic side sectional side view of another version of an exhaust tube of the present invention;

FIG. 3b is a schematic side sectional side view of another version of an exhaust tube of the present invention; and

FIG. 4 is an illustrative block diagram of a computer program product for operating a computer controller system according to the present invention.

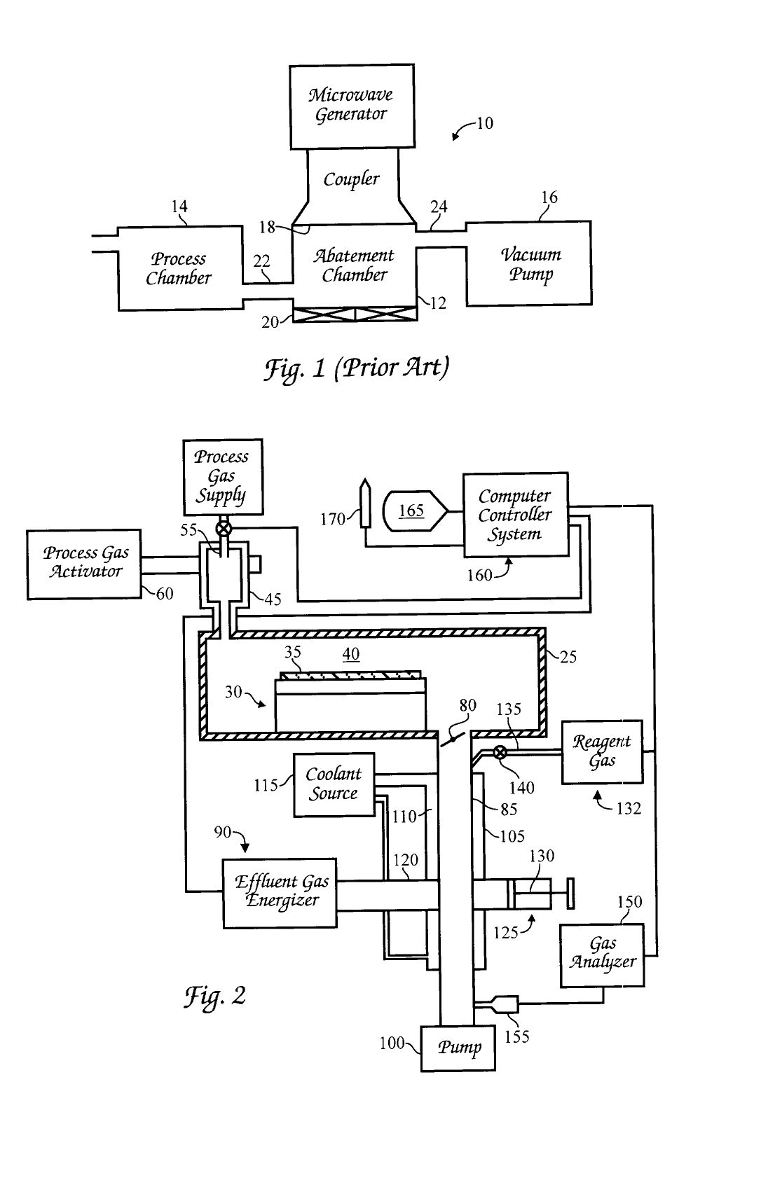

### DESCRIPTION

The present invention relates to a semiconductor process chamber and a gas treatment apparatus and process for abatement of hazardous gas content, and in particular persistent fluorine-containing compounds (PFCs), of the effluent of the semiconductor process chamber.

An exemplary semiconductor processing apparatus, as illustrated in FIG. 2, comprises a process chamber 25 having a support 30 adapted for holding a substrate 35. Typically, the substrate 35 is processed in a process zone 40 comprising a volume of from about 10,000 to about 50,000 cm³.

Activated or energized process gas for processing the substrate 35 is formed in the process zone, or is introduced into the process zone 40 from a remote chamber 45. By “remote” it is meant that the center of the remote chamber 45 is at a fixed upstream distance from the center of the process zone 40.

Providing a remote chamber 45 allows recombination of some of the activated gas species during transport of the species from the remote chamber 45 to the substrate 35 to provide a more controlled process. Preferably, the remote chamber 45 comprises a cavity at a distance of at least about 50 mm, and more preferably from 100 to 600 mm, upstream from the process zone 40. The remote chamber 45 comprises a process gas distributor 55, and a gas activator 60 that couples microwave or RF energy into the process gas to activate the process gas by ionization or dissociation. In the version shown in FIG. 2, the gas activator 60 comprises a microwave gas activator for coupling microwaves into the process gas in the remote chamber 45. The microwave gas activator comprises a commercially available microwave generator that operates at a power level of about 200 to about 3000 Watts, and at a frequency of about 800 MHZ to about 3000 MHZ. Preferably, the remote chamber 45 is sized and shaped to provide a low Q cavity to allow matching of load impedance to the output impedance of the microwave generator over a broad range of impedance values. More preferably, the remote chamber 45 is a cylindrical tube made of a dielectric material, such as quartz, aluminum oxide, or monocrystalline sapphire, that is transparent to microwaves and is non-reactive to the process gas.

Spent process gas and etchant byproducts are exhausted from the process chamber 25 through an exhaust system that comprises a gas treatment apparatus 75 of the present invention, and that is capable of achieving a minimum pressure of about 10⁻³ mTorr in the process chamber 25. The exhaust system further comprises a throttle valve 80 for controlling the pressure in the chamber.

Generally, the gas treatment apparatus 75 is part of the exhaust system, or vive versa, and comprises an exhaust tube 85 for exhausting effluent from the process chamber. A gas energizer 90 such as a microwave generator, or an RF energy coupling system, such as a pair of facing electrodes or an inductor coil, energizes the effluent gas in the exhaust tube 85. For example, in the embodiment shown in FIG. 2, the gas energizer 90 comprises a microwave generator that couples microwaves into the exhaust tube to energize and dissociate the effluent to reduce the hazardous gas content of the effluent. The configuration of the exhaust tube 85 and the gas energizer 90 complement one another to maximize the energy applied to the effluent in the exhaust tube, and to allow the effluent to flow through the exhaust tube in a continuous stream of effluent, as described below.

The exhaust tube 85 preferably comprises an enclosed conduit through which a continuous stream of effluent flows as the effluent is energized by the gas energizer to abate the hazardous gas content of the effluent. The exhaust conduit 85 has an inlet that forms a gas tight seal with an exhaust port of the process chamber 25, and an outlet that forms a gas tight seal with a vacuum pump 100. The exhaust tube 85 is composed of gas impermeable material that has sufficient strength to withstand operating vacuum type pressures of 10−7 Torr. In addition, the exhaust tube 85 is made from material that is resistant to erosion from the energized effluent in the tube, and that withstands the high operating temperatures of conventional process chambers. The exhaust tube 85 should also have a transparent window that is transparent to the radiation coupled to the effluent, such as the microwave or RF radiation. The exhaust tube 85 can be composed of a ceramic material such as quartz (silicon dioxide) or polycrystalline aluminum oxide.

Preferably, the exhaust tube 85 is made from monocrystalline sapphire, which is single crystal alumina that exhibits high chemical and erosion resistance in erosive gaseous environments, especially effluent gases that contain fluorine-containing compounds and species. The exhaust tube 85 of monocrystalline sapphire provides a unitary tubular structure having a cherrically homogeneous composition that has several advantages over polycrystalline materials. The term “monocrystalline” commonly refers to a single crystal material or one that comprises a few (typically 10 or fewer) large ceramic crystals that are oriented in the same crystallographic direction, i.e, having crystallographic planes with miller indices that are aligned to one another. The large crystals within monocrystalline sapphire typically have an average diameter of about 0.5 to about 10 cm, and more typically from 1 to 5 cm. In contrast, conventional polycrystalline ceramic materials have small grains or crystals with diameters on the order of 0.1 micron to 50 micron, which is smaller by a factor of at least about 10⁵ to about 10⁷. The ceramic crystals in the monocrystalline sapphire exhaust tube 85 are oriented in substantially the same single crystallographic direction, and provide exposed surfaces having little or no impurity or glassy grain boundary regions that can erode rapidly in erosive fluorine-containing environments. The continuous and uniform crystallographic structure provided by the monocrystalline sapphire exhaust tube 85 exhibits reduced erosion or particulate generation. In addition, monocrystalline sapphire has a high melting temperature that allows use of the exhaust tube 85 at high temperatures exceeding 1000° C. or even exceeding 2000° C.

The shape and size of the exhaust tube 85 are selected to provide unrestricted and continuous flow of effluent from the process chamber 25 while preventing back diffusion of the effluent into the process chamber. Preferably, the exhaust tube 85 comprises a cross-sectional area (in a plane perpendicular to its long axis) that is sufficient large to flow the effluent gas from the chamber to flow into the tube at a rate that is equal to or greater than the rate at which process gas is supplied to the chamber, otherwise, a back pressure of process gas is formed in the process chamber. Preferably, the exhaust tube 85 comprises a diameter of at least about 5 mm, and most preferably of at least about 35 mm.

Most preferably, the exhaust tube 85 comprises a hollow cylinder having a longitudinal central axis that is oriented parallel to the direction of the flow path of effluent through the tube, and which can be easily adapted to existing process chamber 25 designs. The length of the exhaust tube 85 is sufficiently long to allow the effluent to remain resident in the tube for a sufficient time to abate substantially all of the hazardous gas content of the effluent. The precise length of the exhaust tube 85 depends on a combination of factors including the diameter of the exhaust tube, the composition and peak flow rate of the effluent, and the power level applied to the abatement plasma. For a typical etching process comprising a process gas of CF₄, O₂, and N₂ at total flow of about 1000 sccm, and a microwave gas energizer 90 operated at about 1500 watts, a sufficient resident time is at least about 0.01 seconds, and more preferably about 0.1 seconds. A suitable length of exhaust tube 85 that provides such a residence time, comprises a cylindrical tube having a cross-sectional diameter of 35 mm, and a length of from about 20 cm to about 50 cm.

Preferably, exhaust tube 85 is constructed and integrated with the chamber, to provide a laminar flow of effluent through the tube that undergoes little or no turbulence that would otherwise redirect the flow of effluent in directions other than along the longitudinal axial direction of the tube. In a preferred version, the exhaust tube comprises a cylinder having an internal flow surface that is parallel to the direction of the flow of the effluent through the exhaust tube, and that is substantially absent or free of projections or recesses that alter the effluent flow path or provide a non-laminar flow of effluent. The inner surfaces of the exhaust tube 85 comprise a surface roughness having a Reynolds number of less than about 10. The smooth-finish of the inner surface of the exhaust tube 85, in combination with a vertical orientation of the tube directly beneath the process chamber 25, as shown in FIG. 2, provides a more laminar and less turbulent flow of effluent along the flow path. The laminar flow eliminates turbulence of the effluent gas flow stream and reduces the possibility that effluent gas will diffuse back into the process chamber 25. Positioning the exhaust tube 85 further downstream from the exhaust throttle valve 80, as shown in FIG. 2, further reduces the possibility of a back flow of effluent gas from entering and contaminating the process chamber 25 because the pressure in the exhaust tube 85 is lower than the pressure in the process chamber. In addition, a laminar flow of effluent allows energizing radiation to be coupled in a high strength in the region immediately adjacent to the inner surface of the exhaust tube 85 to form a higher density of energized effluent gas or plasma. Also, because the effluent flows continually and uniformly past the inner surface of the exhaust tube 85, the deposition of byproducts on the inner surface, which would otherwise accumulate and impede the coupling of the ionizing radiation, make it unnecessary to frequently clean the exhaust tube 85.

The gas treatment apparatus 75 of the present invention also includes a cooling jacket 105 enclosing the exhaust tube 85, forming an annulus 110 through which a coolant is passed to remove excess heat generated by the abatement plasma. The material of the cooling jacket 105 is selected to withstand the mechanical and thermal stresses of the application. Preferably the material of the cooling jacket 105 comprises a coefficient of thermal expansion, similar to that of the exhaust tube 85 so that the dimensions of the cooling annulus 110 remain constant. More preferably, the cooling jacket 105 further comprises a window of material transparent to microwave and RF radiation so that the gas energizer can couple the ionizing radiation through the cooling jacket 105 and coolant to the effluent inside the exhaust tube 85, as shown in FIG. 2. Suitable materials for the cooling jacket 105 include aluminum oxide, quartz, sapphire, and monocrystalline sapphire.

The cooling jacket 105 can be any size and shape that allow it to cover and pass fluid over the portion of the exhaust tube 85 in which the abatement plasma is formed. Preferably, the cooling jacket 105 is a tube that is substantially the same length as the exhaust tube 85, and has a central axis along its length that coincides with that of the exhaust tube 85. More preferably, the cooling jacket 105 has an axial length and an inner cross-sectional area in a plane perpendicular to the central axis that forms an annulus 110 sufficiently large to adequately cool the exhaust tube 85, yet not obstruct the transmission of ionizing radiation into the exhaust tube 85. Accordingly, the precise dimensions of the cooling jacket 105 will depend on those of the exhaust tube 85, the flow rate and specific heat capacity of the coolant used, and the power level of the abatement plasma. For the cylindrical exhaust tube 85 described above, a suitable cooling jacket 105 would also be a hollow cylinder surrounding and sealed at either end to the exhaust tube 85 and having a length of from about 20 cm to about 50 cm, and an inner diameter of from about 6 cm to about 40 cm. Providing a rough finish on an outer surface of the exhaust tube 85, such that the flow of coolant along the surface is broken up, ejects heated liquid away from the hot surface of the exhaust tube 85 causing cooler liquid to replace it, thereby enhancing the cooling. Preferably the finish of the outer surface of the exhaust tube 85 comprises a Reynolds number of about 70 or greater. Coolant is supplied to the annulus 110 of the cooling jacket 105 from a coolant chiller-recirculator 115 through one or more pairs of inlet and outlet ports at a rate sufficient to remove the excess heat generated by the plasma in the exhaust tube 85. It has been found that a coolant flow of from about 2 liters/min (^{˜}0.5 gpm) to about 6 liters/min (^{˜}1.5 gpm) is sufficiently high to remove the excess heat. Preferably, the coolant comprises a fluid having little or no conductance such as deionized water.

The gas energizer 90 comprises a source of energetic radiation that couples microwave or RF energy to the effluent in the exhaust tube 85 to form an activated gas or plasma. In a preferred version, the gas energizer 90 comprises a microwave gas energizer capable of producing microwaves having frequencies of from about 2.45 to about 10 GHz, at a power output of at least 500 watts. More preferably the microwave gas energizer 90 has a variable power output which can be remotely adjusted by an operator or a controller from about 500 to about 5000 watts. The microwave gas energizer 90 is preferred because it generates abatement plasmas having a high concentration of dissociated gas with high average electron energies, that react with each other to generate non-hazardous species or compounds in the effluent.

The microwave gas energizer 90 can comprise any commercially available microwave generator, such as for example, a microwave generators from Daihen Corporation, Osaka, Japan. The microwave gas energizer 90 further comprises a waveguide 120 for coupling the microwave radiation from a microwave source to the effluent in the exhaust tube 85, and a tuning assembly 125 for concentrating or focusing the microwave radiation inside the exhaust tube. Generally, the waveguide 120 has a rectangular cross-section, the interior dimensions of which are selected to optimize transmission of radiation at a frequency corresponding to the operating frequency of the microwave generator. For example, for a microwave generator operating at 2.45 GHz, the waveguide 120 forms a rectangle of 5.6 cm by 11.2 cm. The tuning assembly 125 comprises a short segment of waveguide that is closed on one end, and that is positioned on the opposite side of the exhaust tube 85 from and in line with the waveguide 120. A plunger 130 is used to alter the axial length of a cavity defined by the tuning assembly 125 to vary the point at which the electromagnetic field is concentrated. This plunger 130 is not meant to be moved during routine operation, rather it is positioned during initial startup to attain highest possible electric field inside the exhaust tube 85. Once properly positioned, the plunger 130 is fixed within the tuning assembly 125.

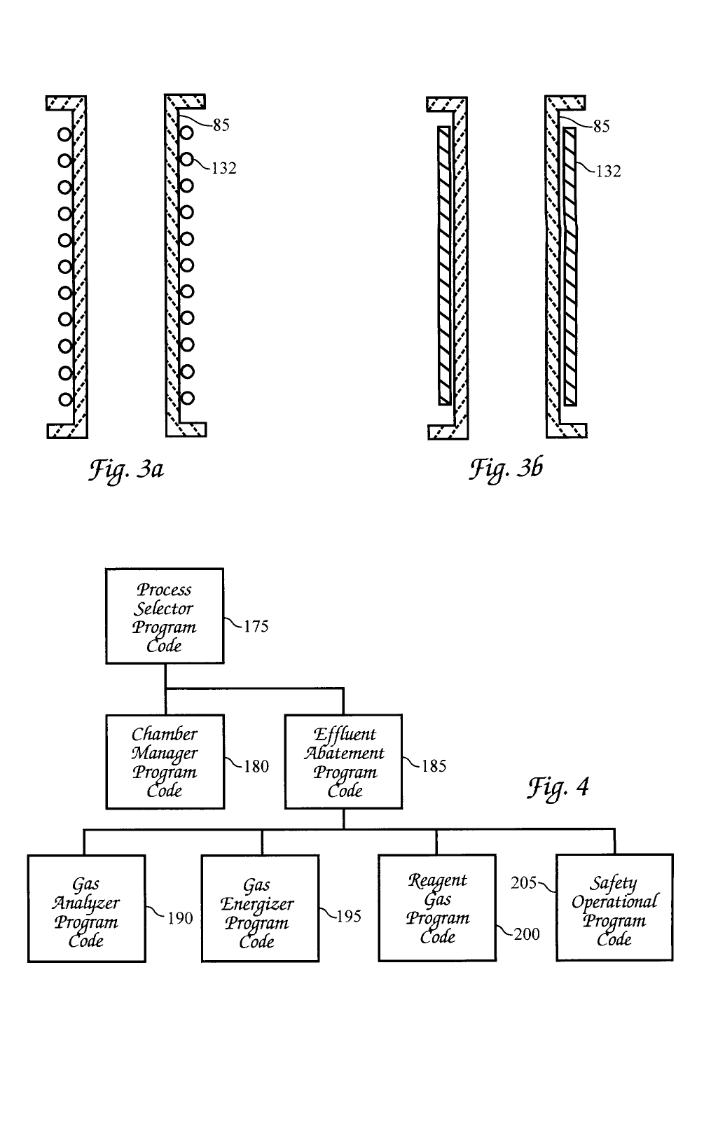

In another embodiment, the gas energizer 90 comprises a plasma generator that provides RF energy to the effluent in the exhaust tube 85 to energize and dissociate the effluent to form ionized plasma. In one version, the RF gas energizer 90 comprises an inductor antenna 132 consisting of one or more inductor coils having a circular symmetry with a central axis coincident with the longitudinal vertical axis that extends through the center of the exhaust tube 85, as shown in FIG. 3a. For example, the inductor antenna 132 can comprise a longitudinal spiraling coil that wraps around the exhaust tube 85 to couple RF energy in the effluent traveling through the exhaust tube. Preferably, the inductor antenna 132 extends across a length that is sufficiently long to energize an extended path-length of effluent gas flowing thorough the exhaust tube to abate substantially all the hazardous gas species in the effluent, as the effluent flows through the exhaust tube.

Alternatively, or in addition to the inductor coil, the RF gas energizer 90 can also comprise of a pair of electrodes 134 positioned within or adjacent to the exhaust tube 85 to form a capacitively coupled field in the exhaust tube 85, as shown in FIG. 3b. In a preferred version, the electrodes 134 comprise flat parallel plates separated by a distance that is sufficiently small to couple energy into the effluent gas flowing between the electrode plates. More preferably, the electrodes 134 comprise opposing semi-cylindrical curved plates that are aligned on the walls of the exhaust tube. As with the inductor antenna, the length of each of the facing electrodes 134 is sufficiently long to energize an extended path-length of effluent gas that flows thorough the exhaust tube to abate substantially all the hazardous gas species in the effluent.

During operation of the gas treatment apparatus in a typical semiconductor process, a semiconductor substrate 35 is placed on the support in the process chamber 25, and a process gas comprising fluorine-containing gas such as CF₄, C₂F₆, SF₆, C₃ F₈, and CH₃F, is introduced into the remote chamber 45 through the process gas distributor 55. The process gas is activated by the gas activator 60 in the chamber 25 to process the substrate 35 in a microwave activated gas or an RF plasma gas. During and after processing, an effluent gas stream of spent process gas and gaseous byproducts are exhausted from the process chamber 25 through the exhaust tube 85 of the exhaust system and gas treatment apparatus.

In the exhaust tube 85, a RF energy or microwave energy, is coupled to the continuous stream of effluent flowing through the exhaust tube, to form an abatement plasma in which hazardous gas components in the effluent are dissociated or reacted with one another to substantially abate the hazardous gas content of the effluent. The electromagnetic radiation raises the energy of some electrons of the atoms of the effluent gas molecules to energies from 1 to 10 eV, thereby freeing electrons and breaking the bonds of the gas molecules to form dissociated atomic gaseous species. In an energized plasma gas, avalanche breakdown occurs in the gaseous stream when the individual charged species electrons and charged nuclei are accelerated in the prevalent electric and magnetic fields to collide with other gas molecules causing further dissociation and ionization of the effluent gas.

The ionized or dissociated gaseous species of the energized effluent react with each other, or with other non-dissociated gaseous species, to form non-toxic gases or gases that are highly soluble in conventional gas scrubbers. For example, the hazardous or environmentally undesirable CF₄ gas is dissociated by microwave energy to form gaseous carbon and fluorine species that react with oxygen gas in the effluent to form CO₂ gas which is much less hazardous, and can be removed by conventional water scrubbers. The dissociated fluorine species react with hydrogen to form HF a soluble compound that is also easily removed from the effluent gas stream by a wet scrubber. In another example, dissociated or ionized NF₃ gas (which is toxic) reacts with hydrogen gas to form N₂ which is non-toxic, and HF which is soluble in a water scrubber. For many hazardous gas compositions of the effluent gas, the energy coupled to the effluent is preferably microwave energy which provides a more highly dissociated gaseous species than RF energy. However, instead of using microwaves, the effluent can also be activated by RF energy, as described above.

In this manner, the gas treatment apparatus 75 substantially abates the hazardous gas emissions in the exhaust tube by dissociating and reacting the effluent process gas byproducts with each other without changing the process conditions in the chamber. The gas treatment apparatus 75 further provides a laminar and non-turbulent flow of effluent gas through the exhaust tube 85 that reduces the turbulence of the effluent gas flow stream and prevents back-diffusion of spent process gas into the chamber 25. Moreover, the emissions of the effluent gas are abated in a continuous flow stream which do not constrict or limit flow rates of process gas into the chamber, thereby providing a larger window of process conditions that can be performed in the chamber. Also, deposition of gaseous reaction byproducts on the inner surface of the exhaust tube, which would otherwise accumulate and impede the coupling of the ionizing radiation, is reduced by forcing the effluent to flow continuously past the inner surfaces of the exhaust tube 85.

In another embodiment, the gas treatment apparatus 75 includes a reagent gas mixer system 132 for mixing reagent gas into the effluent gas stream, before or after the effluent is energized, to enhance abatement of the hazardous gas emissions. When added before the effluent is energized, the reagent gas dissociates or forms energized species that react with the energized hazardous gas species to create gaseous compounds that are non-toxic, or soluble and easily removed by a wet scrubber located downstream in the exhaust system. The addition of even a small amount of reagent gas to the effluent gas stream can significantly improve abatement efficiency. For example, the addition of a small amount of hydrogen can increase the abatement of fluorine-containing gases by reacting with dissociated fluorine atoms to form gaseous HF which is soluble and is easily removed by the downstream water scrubber. Similarly, the addition of oxygen can abate CF₄ emissions by removing gaseous carbon or carbon monoxide by forming CO₂. The reagent gas is added to the effluent gas stream through a reagent gas port 135 positioned sufficiently close to the inlet of the exhaust tube 85 to allow the reagent gas to completely mix with and react with the hazardous gas in the effluent stream before the effluent exits from the exhaust tube. Preferably, the reagent gas port 135 is located less than about 10 cm from the inlet of the exhaust tube 85. Preferably, the reagent gas port 135 comprises an injection nozzle outlet that directs the reagent gas stream into the exhaust tube, such that the reagent gas forms a laminar stream flowing in the same direction as the direction of the laminar flow of the effluent, and along the inner surface of the exhaust tube 85. For example, the outlet of the reagent gas port 135 is preferably in an angular orientation relative to the internal surface of the exhaust tube 85 to flow the reagent gas stream into the exhaust tube 85 in the same direction as the effluent gas stream. More preferably, a valve 140 (or mass flow controller) in the reagent gas port 135 allows an operator or an automatic control system to adjust the volumetric flow of the reagent gas to a level that is sufficiently high to abate substantially all the hazardous gas emissions of the effluent.

In yet another embodiment, the gas treatment apparatus 75 comprises a gas analyzer 150 having a gas analysis probe 155 for detecting and monitoring the composition or concentration of hazardous gas components in the effluent stream, either before or after the effluent is energized. Preferably, the gas analysis probe 155 is mounted near the outlet of the exhaust tube 85, well below the abatement plasma generation zone, and more preferably, about 10 cm to about 200 cm from the outlet of the exhaust tube, to measure the hazardous gas content of the energized effluent gas. The gas analyzer 150 comprises any commercially available gas analyzer, such as for example, the RGA 300 system commercially available from Stanford Research Systems, Sunnyvale, Calif. The gas analyzer 150 is programmed to analyze the composition of the effluent gas, especially the hazardous gas concentration, and provide an output signal in relation to the hazardous gas content, to a computer controller system 160 that controls and adjusts the operation of the gas treatment apparatus 75 and of process chamber 25 according to the output signal.

In operation, the gas analyzer 150 continuously monitors the hazardous gas content of the effluent emitted from the exhaust tube 85 and provides a continuous output signal, or a safety level output signal, that is triggered when the hazardous gas content of the effluent exceeds a safety level. The computer controller system 160 comprises a computer readable medium having computer readable program code embodied therein that monitors the output signal(s) from the gas analyzer and performs at least one of the following steps: (i) adjusts the operating power level of the gas energizer 90 to reduce the hazardous gas content of the effluent, (ii) adjusts process conditions in the process chamber 25 to reduce the hazardous gas content of the effluent, (iii) adds a reagent gas to the effluent gas to reduce the hazardous gas emissions, (iv) terminates a process conducted in the process chamber 25, or (v) provides an alarm signal to notify an operator of dangerously high levels of hazardous gas in the effluent.

The computer controller system 160 preferably operates the process chamber 25 and gas treatment apparatus 75 and comprises a computer program code product that controls a computer comprising one or more central processor units (CPUs) interconnected to a memory system with peripheral control components, such as for example, a PENTIUM microprocessor, commercially available from Intel Corporation, Santa Clara, Calif. The CPUs of the computer control system 160 can also comprise ASIC (application specific integrated circuits) that operate a particular component of the chamber 25 or the gas treatment apparatus 75. The interface between an operator and the computer system is a CRT monitor 165 and a light pen 170, as shown in FIG. 2. The light pen 170 detects light emitted by the CRT monitor 165 with a light sensor in the tip of the pen 170. To select a particular screen or function, the operator touches a designated area of the CRT monitor 165 and pushes a button on the pen 170. The area touched changes its color or a new menu or screen is displayed to confirm the communication between the light pen and the CRT monitor 165. Other devices, such as a keyboard, mouse or pointing communication device can also be used to communicate with the computer controller system 160.

The computer program code operating the CPU(s) and other devices of the computer can be written in any conventional computer readable programming language, such as for example, assembly language, C, C⁺⁺, or Pascal. Suitable program code is entered into a single file, or multiple files, using a conventional text editor and stored or embodied in a computer-usable medium, such as a memory system of the computer. If the entered code text is in a high level language, the code is compiled to a compiler code which is I nked with an object code of precompiled windows library routines. To execute the linked and compiled object code, the system user invokes the object code, causing the computer to load the code in memory to perform the tasks identified in the computer program.

The computer program code comprises one or more sets of computer instructions that dictate the timing, process gas composition, chamber pressure and temperature, RF power levels inside the chamber, susceptor positioning, and other parameters of the process chamber 25. The computer program instruction set also controls operation of the gas treatment apparatus 75, and settings for power levels of the energy coupled into the exhaust tube 85, the flow levels and composition of reagent gas introduced into the exhaust tube 85, and the alarms and other safety operational modes of the gas treatment apparatus 75 or process chamber 25 that are triggered by a predefined concentration of hazardous gas in the effluent, or by the presence of a toxic hazardous gas even in minute trace levels in the effluent.

A preferred version of the computer program code, as illustrated in FIG. 4, comprises multiple sets of program code instructions, such as a process selector and sequencer program code 175 that allows an operator to enter and select a process recipe, and that executes operation of the process recipe in a selected process chamber 25, chamber manager program code 180 for operating and managing priorities of the chamber components in the process chamber 25, and effluent abatement program code 185 for operating the gas treatment apparatus 75. While illustrated as separate program codes that perform a set of tasks, it should be understood that these program codes can be integrated, or the tasks of one program code integrated with the tasks of another program code to provide a desired set of tasks. Thus the computer controller system 160 and program code described herein should not be limited to the specific embodiment of the program codes described herein, and other sets of program code or computer instructions that perform equivalent functions are within the scope of the present invention.

In operation, a user enters a process set and process chamber number into the process selector program code 175 via the video interface terminal 165. The process sets are composed of process parameters necessary to carry out a specific process in the chamber 25, and are identified by predefined set numbers. The process selector program code 175 identifies a desired process chamber, and the desired set of process parameters needed to operate the process chamber for performing a particular process. The process parameters include process conditions, such as for example, process gas composition and flow rates, chamber temperature and pressure, plasma parameters such as microwave or RF bias power levels and magnetic field power levels, cooling gas pressure, and chamber wall temperature.

The process selector program code 175 executes the process set by passing the particular process set parameters to the chamber manager program code 180 which control multiple processing tasks in different process chambers according to the process set determined by the process selector program code 175. For example, the chamber manager program code 180 comprises program code for etching a substrate or depositing material on a substrate in the chamber 25. The chamber manager program code 180 controls execution of various chamber component program code instructions sets which control operation of the chamber components. Examples of chamber component control program code include substrate positioning instructions sets that control robot components that load and remove the substrate onto the support 30, process gas control instruction sets that control the composition and flow rates of process gas supplied into the chamber 25, pressure control instruction sets that set the size of the opening of the throttle valve 80, and plasma control instruction sets that control the power level of the plasma activator 90. In operation, the chamber manager program code 180 selectively calls the chamber component instruction sets in accordance with the particular process set being executed, schedules the chamber component instruction sets, monitors operation of the various chamber components, determines which component needs to be operated based on the process parameters for the process set to be executed, and causes execution of a chamber component instruction set responsive to the monitoring and determining steps.

The effluent abatement program code 185 comprises program code instruction sets for monitoring the concentration of predefined hazardous gases in the effluent gas stream, and operating the process chamber or gas treatment components in relationship to the hazardous gas content/composition in the effluent gas stream. A preferred structure of the effluent abatement program code 185 comprises (i) gas analyzer program code 190 for receiving the output signals of the hazardous gas content and composition (or safety level output signal) from the gas analysis probe 155 and storing the output signals in an Effluent Gas Composition Table that is periodically surveyed by the other program code instruction sets, (ii) gas energizer program code 195 for operating the gas energizer 90 in relation to the output signals in the Table, (iii) reagent gas program code 200 for operating the reagent gas mixer 132, and (iv) safety operational program code 205 for monitoring the emission levels of the hazardous gas in the effluent, and adjusting operation of the process chamber to reduce or substantially eliminate the hazardous gas emissions.

The gas analyzer program code 190 monitors the composition or concentration of hazardous gas in the energized effluent as determined by the gas analyzer 150, and receives the output signals of the hazardous gas content and composition (or the safety level output signal) from the gas analysis probe 155. The gas analyzer program code 190 stores the output signals in an Effluent Gas Composition Table that is periodically surveyed by the other program code instruction sets. Alternatively, or in combination with the storage function, the gas analyzer program code 190 passes a safety level output signal to other program code instructional sets, when the hazardous gas content in the effluent gas exceeds a predefined operational safety level. The gas analyzer program code 190 can also be integrated into the gas analyzer 150, instead of being resident in the computer controller system.

The gas energizer program code 195 includes a program code instruction sets for adjusting power to the gas energizer 90 in response to signals passed by the gas analyzer program code 190. The power level of the RF or microwave energy coupled to the exhaust tube 85, is controlled in relation to the hazardous gas content in the effluent gas stream. For example, when an increase in hazardous gas content is detected, the gas energizer program code 195 increases the power level of the gas energizer 90 to couple more energy into the effluent gas to increase dissociation and ionization of the effluent gas species to reduce the hazardous gas emissions of the effluent. Conversely. upon detection of a decrease in hazardous gas content, the gas energizer program code 195 can decrease the power level of the gas energizer 90 to couple less energy into the effluent gas.

The reagent gas program code 200 includes program code instruction sets for controlling the reagent gas composition and flow levels through the reagent gas mixer 132 to further reduce the hazardous gas emissions in the effluent. Typically, the reagent gas program code 200 adjusts the opening of one or more reagent gas valves 140 in response to the output signals passed by the gas analyzer program code 190 (or upon verification from the Effluent Gas Composition Table that an output signal has exceeded a safety level). When an increase in hazardous gas content is detected, the reagent gas program code 200 activates a flow, or increases a flow rate, of reagent gas into the exhaust tube 85 to further reduce the hazardous gas emissions, and vice versa.

The safety operational program code 205 operates in conjunction with the other program code instruction sets and the gas analyzer 150 to adjust operation of the process chamber components or the gas treatment apparatus in relation to the levels of hazardous gas in the effluent stream to reduce or eliminate the hazardous gas emissions. For example, the safety operational program code 205 can be programmed to shut-down operation of the process chamber 25 upon detection of a predefined concentration of hazardous gas in the exhaust effluent, or of the presence of toxic hazardous gas even in minute trace levels in the effluent. Typically, when toxic gases are used in the processing of the substrate, several safety shut-off valves are on each gas supply line of the gas distributor 55, in conventional configurations. The safety operational program code 205 provides a trigger signal to the process gas control instructions set of the chamber manager program code 180 to close the safety shut-off valves when the concentration of hazardous gas in the effluent reaches a predefined level. Conversely, when the safety operational program code 205 receives a low or zero emissions level signal from the output of the gas analyzer 150, the program code provides a control signal that instructs the chamber manager program code 180 to continue to operate the process chamber 25 in the current operational mode, and that also instructs the effluent abatement program code 185 to continue to operate the gas treatment apparatus 75 in its current operational mode.

The safety operational program code 205 can also activate other safety operational modes of the gas treatment apparatus 75 or other components of the hazardous gas content when the hazardous gas emissions exceed a predefined safety level. For example, the safety operational program code 205 can initiate a controlled shutdown of the process chamber 25 when a safety level output signal is passed to the chamber manager program code 180 to ramp up/down the process gas mass flow controllers, until a flow rate of process gas that reduces the hazardous gas content in the effluent to below acceptable safety levels, is achieved. In operation, the safety operational program code 205 repeatedly reads the latest effluent gas composition in the Effluent Gas Composition Table, compares the readings to a signal from the mass flow controllers controlling process gas flow into the chamber 25, and sends instructions to adjust the flow rates of the process gas as necessary to reduce or entirely eliminate the hazardous gas emissions in the effluent. Alternatively, the safety operational program code 205 performs these operations when it receives a safety level output signal. Typically, this program code is set to operate when the concentration of hazardous gas in the effluent exceeds a predetermined value, such as a concentration of from about 0.1% to about 10%.

In another example, the safety operational program code 205 can also operate an alarm or an indicator, such as a LED light, to indicate a dangerous level of toxic or hazardous gas in the effluent gas stream; or provide a metering display, such as a graphic real-time image that shows in real time the level of emissions of hazardous gas for monitoring by an operator. This safety feature allows an operator to monitor and prevent accidental emissions of hazardous gas into the atmosphere. The same signal can be used to maintain the processing apparatus 35 in a non-operational mode, or to activate the safety shut-off valves when an unsafe process condition is detected. In this manner, the safety operational program code 205 operates the process chamber and the gas treatment apparatus to provide an environmentally safe apparatus.

Although the present invention has been described in considerable detail with reference to certain preferred versions, many other versions should be apparent to others skilled in the art. For example, the exhaust tube 85 can be located upstream from the throttle valve 80 to allow precise control of the resident time of effluent in the abatement plasma zone. Also alternative sources or combinations of dissociating or ionizing radiation, can be used to energize the effluent gas. Therefore, the spirit and scope of the appended claims should not be limited to the description of the preferred versions contained herein.

What is claimed is:

1. A gas treatment apparatus for reducing the hazardous gas content of an effluent from a process chamber, the gas treatment apparatus comprising:
(a) an exhaust tube for exhausting the effluent from the process chamber; and
(b) a gas energizer for energizing the effluent flowing through in the exhaust tube to reduce the hazardous gas content of the effluent.

2. The gas treatment apparatus of claim 1 wherein the exhaust tube comprises a length that is sufficiently long to reduce the hazardous gas content of a continuous stream of effluent flowing through the exhaust tube without recirculation the effluent in the exhaust tube.

3. The gas treatment apparatus of claim 1 wherein the exnaust tube comprises a length that is sufficiently long to provide a residence time of the effluent flowing through the exhaust tube that is at least about 0.01 seconds.

4. The gas treatment apparatus of claim 1 wherein the exhaust tube comprises a flow surface that provides a laminar flow of effluent through the exhaust tube.

5. The gas treatment apparatus of claim 4 wherein the exhaust tube comprises a cylinder having an internal flow surface that is parallel to the direction of the flow of the effluent through the exhaust tube, and that is substantially absent projections or recesses that alter the effluent flow path.

6. The gas treatment apparatus of claim 1 further comprising a reagent gas mixer for mixing reagent gas with the effluent to further reduce the hazardous gas content of the effluent.

7. The gas treatment apparatus of claim 1 wherein the exhaust tube is composed of monocrystalline sapphire, and the gas energizer comprises a microwave generator for generating microwaves and a waveguide for coupling microwaves from the microwave generator to the exhaust tube to energize the effluent by microwaves.

8. The gas treatment apparatus of claim 1 wherein the gas energizer comprises a plasma generator for coupling RF energy into the exhaust tube to form a plasma from the effluent, the plasma generator comprising facing electrodes or an inductor coil.

9. The gas treatment apparatus of claim 1 wherein the exiaust tube comprises a distributor plate at an inlet of the exhaust tube, the distributor plate having holes for directing effluent preferentially along a flow surface of the exhaust tube.

10. The gas treatment apparatus of claim 1 further comprising:
(a) a gas analyzer for monitoring the hazardous gas content of the effluent in the exhaust tube and providing an output signal in relation to the hazardous gas content of the effluent; and
(b) a computer controller system comprising a computer readable medium having computer readable program code embodied therein for monitoring the output signal from the gas analyzer, and when the hazardous gas content of the effluent exceeds a safety level, performing at least one of the steps of:
(i) adjusting the operating power level of the gas energizer to reduce the hazardous gas content in the effluent,
(ii) adjusting the process conditions in the process chamber to reduce the hazardous gas content in the effluent,
(iii) activating an alarm or metering display,
(iv) adding a reagent gas to the effluent gas before or after the effluent gas is energized, to reduce the hazardous gas content in the effluent, or
(v) terminating the process being conducted in the process chamber.

11. A process chamber for processing a substrate and reducing emissions of hazardous gas to the environment, the process chamber comprising:
(a) a support for supporting the substrate in the process chamber;
(b) a gas distributor for introducing process gas into the process chamber;
(c) a gas activator for activating the process gas to process the substrate, thereby forming an effluent containing hazardous gas; and
(d) an exhaust system for exhausting and treating the effluent from the process chamber, the exhaust system comprising an exhaust tube for flowing a continuous stream of the effluent therethrough, and a gas energizer for energizing the effluent in the exhaust tube to reduce the hazardous gas content of the effluent.

12. The process chamber of claim 11 wherein the exhaust tube comprises at least one of the following characteristics:
(1) a length that is sufficiently long to reduce the hazardous gas content of the continuous stream of effluent flowing through the exhaust tube without recirculation the effluent in the exhaust tube;
(2) a length that is sufficiently long to provide a residence time of effluent in the exhaust tube that is at least about 0.01 seconds; or
(3) a flow surface that provides a laminar flow of effluent through the exhaust tube, the flow surface being parallel to the direction of the flow of the effluent through the exhaust tube and substantially absent projections or recesses that alter the effluent flow path.

13. The process chamber of claim 11 wherein the gas energizer comprises a microwave generator for generating microwaves and a waveguide for coupling microwaves from the microwave generator to the exhaust tube to energize the effluent in the exhaust tube.

14. The process chamber of claim 11 wherein the gas energizer comprises a plasma generator for coupling RF energy into the exhaust tube to generate a plasma from the effluent in the exhaust tube, the plasma generator comprising facing electrodes or an inductor coil.

15. The process chamber of claim 11 wherein the exhaust tube is composed of monocrystalline sapphire.

16. The process chamber of claim 11 further comprising:
(a) a gas analyzer for monitoring the hazardous gas content of the effluent in the exhaust tube and providing an output signal in relation to the hazardous gas content of the effluent; and
(b) a computer controller system comprising a computer readable medium having computer readable program code embodied therein for monitoring the output signal from the gas analyzer, and when the hazardous gas content of the effluent exceeds a safety level, performing at least one of the steps of:
(i) adjusting the operating power level of the gas energizer to reduce the hazardous gas content in the effluent,
(ii) adjusting the process conditions in the process chamber to reduce the hazardous gas content in the effluent,
(iii) activating an alarm or metering display,
(iv) adding a reagent gas to the effluent gas before or after the effluent gas is energized, to reduce the hazardous gas content in the effluent, or
(v) terminating the process being conducted in the process chamber.

17. A method of reducing the hazardous gas content of an effluent formed during processing of a semiconductor substrate, the method comprising the steps of:
(a) flowing a continuous stream of the effluent through an exhaust tube; and
(b) coupling microwaves or RF energy into the exhaust tube to reduce the hazardous gas content in the continuous stream of effluent flowing through the exhaust tube without recirculation of the effluent in the exhaust tube.

18. The method of claim 17 wherein step (a) comprises the step of flowing the effluent through a path length that is sufficiently long to reduce the hazardous gas content of the effluent as a continuous stream of effluent flows through the exhaust tube.

19. The method of claim 17 wherein step (a) comprises the step of flowing the effluent through a path length that is sufficiently long to provide a residence time of effluent in the exhaust tube that is at least about 0.01 seconds.

20. The method of claim 17 wherein step (a) comprises the step of flowing the effluent in a substantially laminar flow through the exhaust tube.

21. The method of claim 17 further comprising the step of introducing a reagent gas into the effluent to further reduce the hazardous gas content of the effluent.

22. The method of claim 21 wherein the volumetric flow ratio of reagent gas to effluent is sufficiently high to abate substantially all the hazardous gas content of the effluent.

23. The method of claim 17 further comprising the steps of:
(1) analyzing the hazardous gas content of the effluent emitted from the exhaust tube; and
(2) determining if the content of the hazardous gas n the effluent emitted from the exhaust tube exceeds a safety level, and upon such determination, performing at least one of the steps of:
(i) adjusting the operating power level of the gas energizer to reduce the hazardous gas content in the effluent,
(ii) adjusting the process conditions in the process chamber to reduce the hazardous gas content in the effluent,
(iii) activating an alarm or metering display,
(iv) adding a reagent gas to the effluent gas before or after the effluent gas is energized, to reduce the hazardous gas content in the effluent, or
(v) terminating the process being conducted in the process chamber.

24. A process chamber for processing a substrate in a process gas and reducing emissions of hazardous gas to the environment, the process chamber comprising:
(a) a support for supporting the substrate;
(b) a gas distributor for introducing process gas into the process chamber;
(c) a gas activator for activating the process gas to process the substrate thereby forming effluent containing hazardous gas; and
(d) an exhaust system for exhausting and treating effluent from the process chamber, the exhaust system comprising an exhaust tube composed of monocrystalline sapphire, a microwave source for generating microwaves, and a waveguide for coupling microwaves from the microwave source to the exhaust tube, whereby energizing the effluent in the exhaust tube by microwaves reduces the hazardous gas content of the effluent.

25. The process chamber of claim 24 wherein the exhaust tube comprises at least one of the following characteristics:
(1) a length that is sufficiently long to reduce the hazardous gas content of a continuous stream of effluent flowing through the exhaust tube without recirculation the effluent in the exhaust tube;
(2) a length that is sufficiently long to provide an effluent residence time in the exhaust tube that is at least about 0.01 seconds; or
(3) a flow surface that provides a laminar flow of effluent through the exhaust tube, the flow surface being parallel to the direction of the flow of the effluent through the exhaust tube and substantially absent projections or recesses that alter the effluent flow path.

26. A process chamber for processing a semiconductor substrate in a process gas while reducing emissions of a hazardous gas to the environment, the process chamber comprising:
(a) a support for supporting the substrate, a gas distributor for introducing process gas into the process chamber, and a gas activator for activating the process gas to process the substrate, thereby forming effluent containing hazardous gas;
(b) an exhaust system comprising an exhaust tube for exhausting the effluent from the process chamber and a gas energizer for energizing the gas in the exhaust tube to reduce the hazardous gas content of the effluent;
(c) a gas analyzer for monitoring the hazardous gas content of the effluent in the exhaust tube and providing an output signal in relation to the hazardous gas content of the effluent; and
(d) a computer controller system comprising a computer readable medium having computer readable program code embodied therein for monitoring the output signal from the gas analyzer, and when the hazardous gas content of the effluent exceeds a safety level, performing at least one of the steps of:
(i) adjusting the operating power level of the gas energizer to reduce the hazardous gas content in the effluent,
(ii) adjusting the process conditions in the process chamber to reduce the hazardous gas content in the effluent,
(iii) activating an alarm or metering display,
(iv) adding a reagent gas to the effluent gas before or after the effluent gas is energized, to reduce the hazardous gas content in the effluent, or
(v) terminating the process being conducted in the process chamber.

27. The process chamber of claim 26 wherein the computer readable program code on the computer readable medium comprises one or more of:
(1) gas analyzer program code for receiving the output signals relating to the hazardous gas content of the effluent from the gas analyzer, and storing or passing the output signals to other program codes,
(2) gas energizer program code for adjusting a power level of a gas energizer in relation to the output signals,
(3) reagent gas program code for operating a reagent gas mixer that adds reagent gas to the effluent in relation to the output signals, and
(4) safety operational program code that upon receiving an output signal that the hazardous gas content of the energized effluent exceeds a safety level, performs at least one of the steps of (1) adjusting process conditions in the process chamber to reduce the hazardous gas emissions, (2) operating an alarm to indicate a dangerous level of toxic or hazardous gas in the effluent, (3) providing a metering display that shows in real time the level of emissions of hazardous gas, or (4) shutting down the process chamber.

28. A computer program product for operating a gas treatment apparatus and process chamber, to reduce the hazardous gas content of an effluent formed during processing of a semiconductor substrate in the process chamber,
the gas treatment apparatus comprising an exhaust tube for exhausting effluent from the process chamber, a gas energizer for energizing the effluent in the exhaust tube to reduce the hazardous gas content of the effluent, and a gas analyzer for monitoring the hazardous gas content of the effluent in the exhaust tube and providing an output signal in relation to the hazardous gas content of the effluent,
the computer program product comprising a computer usable medium having computer readable program code embodied in the medium, the computer readable program code comprising:
(a) gas analyzer program code for receiving the output signal relating to the hazardous gas content of the effluent from the gas analyzer, and storing or passing the output signal to other program codes; and
(b) safety operational program code that upon receiving an output signal that the hazardous gas content of the energized effluent exceeds a safety level, performs at least one of the steps of (1) adjusting process conditions in the process chamber to reduce the hazardous gas emissions, (2) operating an alarm to indicate a dangerous level of toxic or hazardous gas in the effluent, (3) providing a metering display that shows in real time the level of emissions of hazardous gas, or (4) shutting down the process chamber.

29. The computer program product of claim 28 wherein the computer readable program code comprises gas energizer program code for adjusting a power level of the gas energizer in relation to the output signal to reduce the hazardous gas emissions of the effluent.

30. The computer program product of claim 28 wherein the computer readable program code comprises reagent gas program code for adding reagent gas to the effluent in relation to the output signal to reduce the hazardous gas emissions of the effluent.
